(19) United States
(12) Patent Application Publication
(10) Pub. No.: US 2005/0153491 A1
(43) Pub. Date: Jul. 14, 2005

(54) Process of forming low-strain(relaxed) silicon geranium crystal layer

(76) Inventors: Yang-Tai Tseng, Hsinchu (TW); Pang-Shiu Chen, Hsinchu (TW); Chee-Wee Liu, Hsinchu (TW)

Correspondence Address: BIRCH STEWART KOLASCH & BIRCH, PO BOX 747, FALLS CHURCH, VA, 22040-0747, US

(21) Appl. No.: 10/838,252

(22) Filed: May 5, 2004

(30) Foreign Application Priority Data
Sep. 30, 2003 (TW) 92127105

(51) Int. Cl. H01L 21/00; H01L 21/84; H01L 21/76; C30B 1/00

(52) U.S. Cl. 438/166; 438/680

(57) ABSTRACT

A process of forming a low-strain crystal layer having low cell dislocation, low surface roughness and low thickness comprises: forming at least one crystal layer on a substrate; patterning the crystal layer by exposure and development to form an ion-doping region; doping ions in the ion-doping region of the crystal layer to convert the crystal layer to an amorphous layer; performing a planarization process on the amorphous layer; and annealing the amorphous layer to convert the amorphous layer to a low-strain crystal layer.

### BACKGROUND OF THE INVENTION

1. Field of Invention

The present invention relates to a process of forming a low-strain(relaxed) silicon geranium (SiGe) crystal layer, and more particularly to a process of forming a low-strain(relaxed) SiGe crystal layer with reduced cell (threading) dislocation.

2. Related Art

As there are increasing demands of high operation speed, multi-functional, portability and lightweight features for electronic appliances, the size of a semiconductor device is increasingly reduced while the amount of semiconductor devices per silicon chip is increased. The integrated circuit therefore has been developed to be compact with high operation speed. The way of increasing the operation speed of the semiconductor device with reduced energy constitutes an important issue in the very large scale integration (VLSI) field.

High-speed operation feature of the semiconductor device has a close relationship with the size of the semiconductor device as well as the shifting speed of holes(carriers) in the silicon layer. The size of the semiconductor device is determined by processes implemented to produce the semiconductor device, including exposure and development, selection of a dielectric material and etching performance. Among these factors, the tolerance of the exposure and development, the light source for exposure, and the mask manufacture are the most critical with respect to the size of the semiconductor device. Time and investment are usually needed to improve the technology. An approach known in the art also proposes to increase the shifting speed of electrons and holes. In this approach, various heterogeneous materials are combined, such as GaAs/Si, InP/GaAs, Ge/Si, to produce a semiconductor device having an improved operation speed. The heterogeneous materials include films with different energy gaps, such as GaAs or AlGaAsP, and find principal applications in communication antennas and mobile phones having high-gain and low-noise high frequency amplifiers. The heterogeneous materials can be also used in a semiconductor laser in optical fiber communication, a compact disc reading head and a laser marker. Additionally, the heterogeneous materials can be implemented in light emitting diodes, being widely used in replacement of the traditional light bulb. The combination of elements with cells of different size to form a semiconductor material has been studied for about 20 years. Researches on SiGe material have shown that when a composite layer of Si and Ge is grown on a silicon substrate, a two-dimensional porous layer of electrons and holes is formed at an interface between the SiGe layer and the silicon substrate, which increases electron shift speed in a channel of the semiconductor device and, consequently, the semiconductor device performance. The difference in cells of Si and Ge, which exists in a form of three-dimensional network structure, results in cell dislocation and therefore reduces the strain. Therefore, strain accumulation causing instability of the final semiconductor device can be prevented. Cell dislocation is crucial to the stability of the semiconductor device. If cell dislocation is highly present, the semiconductor device likely generates cracks during thermal cycles. The location of the cell dislocation must not be close to the device to avoid adverse effects once the crack is generated. To find adequate implementation in the semiconductor process, the heterogeneous materials must not generate cell dislocation or the cell dislocation must not be close to the device.

U.S. Pat. No. 5,019,882 discloses a process of forming a silicon and geranium composite layer on a silicon substrate. The composite layer is so thin that cell dislocation is generated. Then, a silicon layer is formed on the composite layer, and partially oxidized into a silicon dioxide layer. Finally, a gate is formed on the silicon dioxide, with a high carrier shift rate in the channel. The operation speed of the semiconductor device is thereby increased.

E. A. Fitzgerald (Appl. Phys. Lett. 59, 811 (1991) discloses an interface with different geranium contents, providing reduced cell mismatch or dislocation. These researches are conducted at high and low temperatures to grow a composite SiGe layer with layers of various Ge content-ratios. It was found that initial layers with slightly varied Ge-contents have less dislocation, and aGe layer subsequently formed on the initial layers with slightly varied Ge-contents has less dislocation layers. These initial layers are used as a substrate for a main device or high-electron-shift-rate structure to reduce cell mismatch or dislocation.

Many researches have been done based on a SiGe layer formed on layers of slightly changing Ge-contents.

In U.S. Pat. No. 6,515,335, a Ge wetting layer is formed on a silicon-on-insulator (SOI). A SiGe island-shaped layer is formed on the Ge wetting layer. A planarized SiGe layer is formed to cover the SiGe island-shaped layer. After a thermal treatment is performed, diffusion occurs between the SiGe island-shaped layer and the planarized SiGe layer to form a uniform low-strain SiGe layer on the insulator. There is no cell dislocation on the topmost SiGe layer.

U.S. Pat. No. 6,291,321 discloses a process of forming layers with slightly varied Ge-contents at different temperatures. Cell dislocation at interfaces between the layers increases due to the roughness of the interfaces. In the disclosure of this patent, the roughness of the interfaces is reduced by performing a chemical mechanical polishing process, which results in a reduction of cell dislocation.

Current technology trends now are focusing on the formation of layers with slightly varied Ge-contents where cell dislocation is well controlled, and the formation of a main SiGe layer on the layers with slightly varied Ge-contents. Generally, the content of Ge is in proportion to the layer thickness. In other words, the higher the Ge content, the thicker the layer and the more serious is the cell dislocation. Currently, the SiGe layer is grown by slightly increasing the Ge-content so that cell dislocation is reduced. However, it adversely opposes to the demand for high operation speed of the semiconductor device. The operation speed increases as the Ge-content increases, but high Ge-content results in a greater thickness and tends to generate cracks. Therefore, a solution is needed to balance between a high Ge-content and a low thickness for the SiGe layer.

### SUMMARY OF THE INVENTION

It is an object of the invention to provide a process of forming a SiGe crystal layer having low stain and reduced cell dislocation to overcome the disadvantages of the prior art.

It is second object of the invention to provide a process of forming a SiGe crystal layer that can be implemented to grow a SiGe epitaxy layer with any amount of Ge-contents.

Furthermore, a third object of the invention is to provide a process of forming a SiGe crystal layer with various thicknesses.

Additionally, a fourth object of the invention provides a process of forming a SiGe crystal layer having a desired amount of Ge-content and a reduced thickness.

To achieve the above and other objectives, the process of forming a low-strain and low-cell-dislocation SiGe crystal layer of the invention includes forming at least one SiGe layer on a semiconductor substrate; defining an ion-implanting region on the SiGe layer by exposure and development using a photomask; doping ions in the ion-implanting region to convert the SiGe crystal layer to an amorphous SiGe layer; performing a planarization process on the semiconductor substrate having the amorphous SiGe layer thereon; and annealing the amorphous SiGe layer to convert the amorphous SiGe layer to a low-strain SiGe crystal layer.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below illustration only, and thus is not limitative of the present invention, wherein:

FIG. 1 is a flowchart of a process of forming a low-strain SiGe crystal layer according to one embodiment of the invention;

FIG. 2A-FIG. 2D are cross-sectional views of a process of forming a low-strain SiGe crystal layer according to variant embodiments of the invention; and

FIG. 3A-FIG. 3D are cross-sectional views of a process of forming a low-strain SiGe crystal layer according to other variant embodiments of the invention.

### DETAILED DESCRIPTION OF THE INVENTION

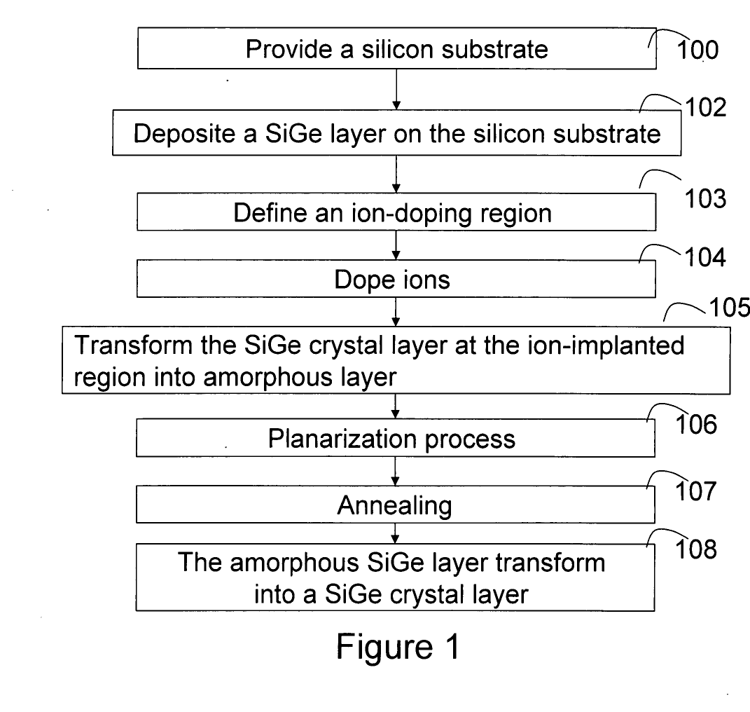

FIG. 1 is a flowchart of a process of forming a low-strain SiGe crystal layer according to one embodiment of the invention. Steps of the process can be performed in different sequences, or some of the steps can be omitted, or performed simultaneously. The sequence and number of steps are not particularly limited to those described in the following embodiments. A silicon substrate is provided at step 100. A SiGe layer is deposited on the silicon substrate at step 102. Exposure and development steps are performed to define an ion-doping region at step 103. Argon ions are doped in the ion-implanted region at step 104. The SiGe crystal layer at the ion-implanted region is transformed into a polycrystalline or amorphous layer at step 105. The silicon substrate with the amorphous SiGe layer is subjected to a planarization process at step 106. An annealing process then is performed at step 107. At step 108, the amorphous SiGe layer is transformed into a SiGe crystal layer after annealing.

At step 102, the SiGe layer can be epitaxy grown on the silicon substrate by, for example, super vacuum chemical vapor deposition or molecule beam epitaxy growth. At step 103, a photo mask is used to define a region on the SiGe layer where the ions are to be doped. At step 104, argon ions are doped in the region defined by the exposure and development processes. The dosage and energy for ion doping may vary depending on the thickness of the SiGe layer to transform the SiGe layer (Si₁₋ₓGeₓ) to the polycrystalline or amorphous crystal (Si₁₋ₓGeₓ). At step 105, the SiGe (Si₁₋ₓGeₓ) layer is converted to a polycrystalline or amorphous SiGe layer. At step 106, the SiGe layer is subjected to a planarization process to further reduce its crystal staggering density and thickness. The time and number of planarization steps are not limited to any specific constraints. Planarization can be further performed at step 107. At step 107, the temperature and duration of annealing are adequately chosen so as to turn the amorphous layer to the SiGe crystal layer. For example, the annealing process can be performed for 30 minutes at 800° C. Via this annealing process, the amorphous SiGe layer is converted to the SiGe crystal layer.

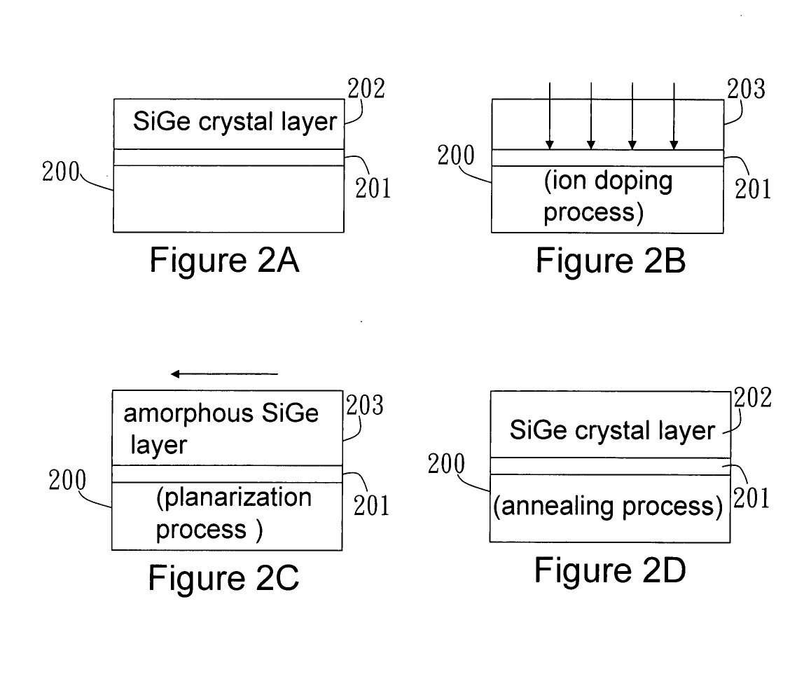

FIG. 2A is a cross-sectional view of a first processing step in a process of forming a low-strain SiGe crystal layer according to an embodiment of the invention. The embodiment includes forming a silicon buffer layer 201 on a Si substrate 200, and depositing a SiGe crystal layer 202 on the silicon buffer layer 201. Deposition of the SiGe crystal layer 202 can be performed via a super vacuum chemical vapor deposition, a molecule beam expitaxy growth, a low pressure vapor deposition (LPVCD) or a rapid thermal chemical vapor deposition (RTVCD). The thickness of the SiGe crystal is about 2000 angstroms. The Ge ratio is about 20% in average. The Ge ratio and the thickness of the SiGe layer can be varied as desired. The SiGe crystal layer 202 can have a laminated structure formed by stacking a plurality of SiGe layers, each layer with a slightly varying Ge ratio to reduce cell dislocation.

FIG. 2B is a cross-sectional view of a second process step in a process of forming a low-strain SiGe crystal layer according to an embodiment of the invention. A photo mask is used to define an ion-implanting region (not shown) on the SiGe crystal layer 202. Then, argon ions are doped in the ion-implanting region (not shown) to convert the SiGe crystal layer 202 to a polycrystalline or amorphous SiGe layer 203. The dosage of argon ions and doping energy depend on the thickness of the polycrystalline or amorphous SiGe layer 203. In an example, doping energy of 60 KeV and argon ions of 1e+14 may be applied to convert the SiGe layer to a polycrystalline or amorphous SiGe layer.

FIG. 2C is a cross-sectional view of a third processing step in a process of forming a low-strain SiGe crystal layer according to an embodiment of the invention. The amorphous SiGe layer 203 is subjected to a planarization process to reduce cell dislocation and the thickness of the amorphous SiGe layer. This third procedure can be further performed after a fourth processing step described hereafter. The planarization process can be a chemical mechanical polishing process.

FIG. 2D is a cross-sectional view illustrating a fourth processing step in a process of forming a low-strain SiGe crystal layer according to an embodiment of the invention. The silicon substrate 200, including the amorphous SiGe layer 203, undergoes an annealing process to convert the amorphous SiGe layer 203 to a SiGe crystal layer. The annealing temperature and time may be selected according to the thickness of the SiGe crystal layer 203 and the used processing equipment. In this embodiment, the annealing process is performed in an inert gas, such as argon gas, under an atmosphere pressure for about 30 minutes and at a temperature of about 800° C. to convert the SiGe layer 203 to a SiGe crystal layer. However, the temperature and the duration of the annealing process may not be limited to the foregoing examples.

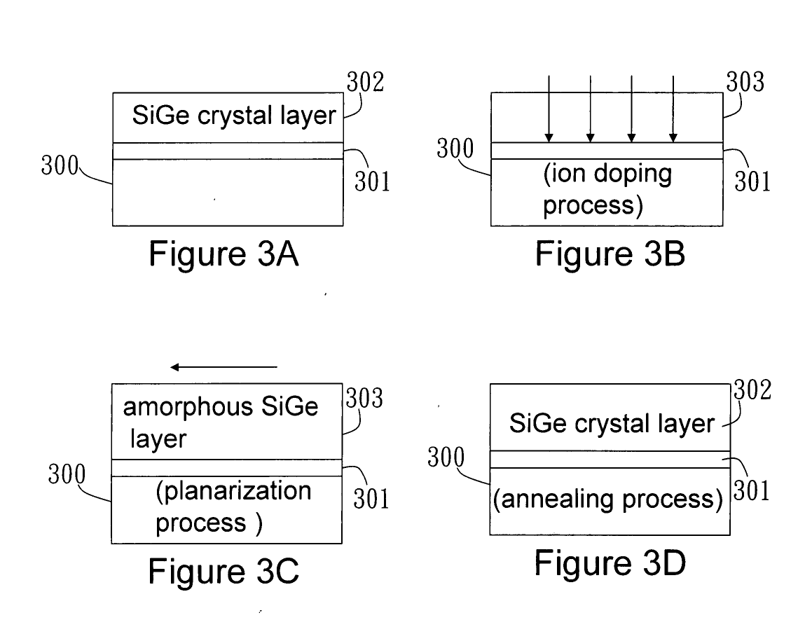

FIG. 3A is a cross-sectional view of a first processing step in a process of forming a low-strain SiGe crystal layer according to another embodiment of the invention. A silicon buffer layer 301 is formed on a silicon substrate 300. A crystal layer 302 is deposited on the silicon buffer layer 301. The crystal layer 302 has cells different from that of the silicon buffer layer. The thickness of the crystal layer 302 can be varied as desired.

FIG. 3B is a cross-sectional view of a second processing step in a process of forming a low-strain SiGe crystal layer according to another embodiment of the invention. A photo mask is used to define an ion-implanting region (not shown) on the crystal layer 302. Then, argon ions are doped in the ion-implanting region (not shown) to convert the crystal layer 302 to a polycrystalline or amorphous layer 303. The dosage of argon ions and doping energy depend on the thickness of the polycrystalline or amorphous layer 303.

FIG. 3C is a cross-sectional view illustrating a third processing step in a process of forming a low-strain SiGe crystal layer according to another embodiment of the invention. The amorphous SiGe layer 203 undergoes a planarization process to reduce cell dislocation and the thickness of the amorphous layer 303. This third alternatively can be performed after the fourth processing step described hereafter. The planarization process can be a chemical mechanical polishing process.

FIG. 3D is a cross-sectional view of a fourth processing step in a process of forming a low-strain SiGe crystal layer according to another embodiment of the invention. The silicon substrate 300, including the amorphous layer 303, undergoes an annealing process to convert the amorphous layer 303 to a crystal layer 302, having less strain. The annealing temperature and time depend on the thickness of the crystal layer 303 and the SiGe crystal layer and the used processing equipment. The annealing process is performed in an inert gas.

The sequence of the processing steps in the process according to the invention is not limited to the above.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A process of forming a low-strain crystal layer, comprising;
forming at least one crystal layer on a substrate;
doping ions in the crystal layer to convert the crystal layer to an amorphous layer;
performing a planarization process on the amorphous layer; and
annealing the amorphous layer to convert the amorphous layer to a low-strain crystal layer.

2. The process of claim 1, wherein the crystal layer includes Si and Ge.

3. The process of claim 1, wherein the crystal layer is formed by super vacuum chemical vapor deposition.

4. The process of claim 1, wherein the crystal layer is formed by a molecule beam epitaxy growth method.

5. The process of claim 1, wherein the crystal layer is formed by a low pressure chemical vapor deposition (LPCVD).

6. The process of claim 1, wherein the crystal layer is formed by a rapid thermal chemical vapor deposition.

7. The process of claim 1, wherein the crystal layer is formed by slightly changing the Ge-content.

8. The process of claim 1, wherein the planarization process includes a chemical mechanical polishing process.

9. The process of claim 1, wherein the ions doped in the crystal layer are argon ions.

10. The process of claim 1, further comprising performing a planarization process after the amorphous layer is converted to a low-strain crystal layer.

11. The process of claim 1, wherein the planarization process includes a chemical mechanical polishing process.

12. The process of claim 1, further comprising defining an ion-doping region in the crystal layer by exposure and development using a photomask, and doping ions in the ion-doping region.

13. A process of forming a low-strain crystal layer, comprising;
forming at least one crystal layer on a substrate;
patterning the crystal layer by exposure and development to form an ion-doping region;
doping ions in the ion-doping region of the crystal layer to convert the crystal layer to an amorphous layer;
performing a planarization process on the amorphous layer; and
annealing the amorphous layer to convert the amorphous layer to a low-strain crystal layer.

14. The process of claim 13, wherein the crystal layer includes Si and Ge.

15. The process of claim 13, wherein the crystal layer is formed by slightly changing the Ge-content.

16. The process of claim 13, wherein the planarization process includes a chemical mechanical polishing process.

17. The process of claim 13, wherein the ions doped in the crystal layer are argon ions.

18. The process of claim 13, further comprising performing a planarization process after the amorphous layer is converted to a low-strain crystal layer.

19. The process of claim 18, wherein the planarization process includes a chemical mechanical polishing process.
